(19) United States
(12) Patent Application Publication
(10) Pub. No.: US 2026/0322332 A1
(43) Pub. Date: Oct. 15, 2026

(54) CLASS A AMPLIFIER CIRCUIT

(71) Applicant: Radial Engineering Ltd., Port Coquitlam (CA)

(72) Inventors: William Craig Hutchison, Port Coquitlam (CA); Emily Swan, Port Coquitlam (CA)

(21) Appl. No.: 19/262,277

(22) Filed: Jul. 8, 2025

(30) Foreign Application Priority Data
Apr. 11, 2025 (CA) 3270664

(51) Int. Cl. H03F 1/26; H03F 3/45

(52) U.S. Cl. CPC H03F 1/26; H03F 3/4508; H03F 3/45179; H03F 3/45376; H03F 2200/03

(57) ABSTRACT

Class A amplifier circuits and methods of operating the Class A amplifier circuits are described. A Class A amplifier circuit comprises a first amplification stage including an operational amplifier with an output pin and a first compensation pin. The output pin outputs a Class A/B amplified signal, while the first compensation pin, originally intended for frequency response adjustment, is repurposed to output an internal signal preceding the Class A/B output stage. A second amplification stage includes a discrete transistor connected to the first compensation pin, in which the internal signal is amplified by the operational amplifier and the discrete transistor in Class A operation to generate an output signal.

### FIELD

The present disclosure relates to amplifier circuits and, more particularly, to operational amplifier-based amplifier circuits utilized in audio signal processing and amplification.

### BACKGROUND

Audio amplifiers deliver high-fidelity sound in a variety of applications, including consumer electronics, professional audio systems, and recording equipment. Among the many classes of amplifiers, Class A/B amplifiers are commonly used because of their efficiency and balance between linearity and power dissipation. Class A/B operation utilizes a push-pull configuration where one active device amplifies the positive half of the signal waveform and another amplifies the negative half.

While Class A/B amplifiers offer practical advantages, they are inherently susceptible to a phenomenon known as “crossover” or “zero-cross” distortion. This distortion results from the nonlinearities introduced during the transition between the active devices as they switch roles at the signal's zero-crossing points. Despite the use of negative feedback to mitigate these effects, residual distortion can persist, especially at low signal levels where its effects are often more noticeable.

In addition to crossover distortion, operational amplifiers (op-amps) used in audio applications can present other challenges, such as thermal modulation and offset voltages. Thermal modulation can occur when the temperature of on-chip components fluctuates due to dynamic power dissipation, affecting signal fidelity. Offset voltages, including input and output DC offsets, can introduce unwanted artifacts such as clicks, pops, or audible noise during operation, especially in circuits with potentiometers or switching mechanisms.

Efforts to overcome these limitations often involve trade-offs, such as the use of DC blocking capacitors, which can introduce their own distortion and bandwidth limitations, or the use of complex active circuitry, such as DC servos, which require careful implementation to avoid additional noise or instability.

Thus, there remains a need for an audio amplifier circuit that reduces crossover distortion and other signal impairments, such as thermal modulation and DC offset artifacts, without compromising signal fidelity.

### SUMMARY

In one aspect, the present disclosure provides a Class A amplifier circuit comprising: a first amplification stage including an operational amplifier having an output pin and a first compensation pin, the output pin being configured to output an amplified signal through a Class A/B output stage, and the first compensation pin, originally intended for internal frequency response adjustment, being repurposed to provide an internal signal prior to the Class A/B output stage; and a second amplification stage arranged subsequent to the first amplification stage and including a discrete transistor, wherein the first compensation pin of the operational amplifier is connected to the discrete transistor in the second amplification stage, such that the internal signal provided by the first compensation pin is amplified by the operational amplifier in Class A operation and is further amplified by the discrete transistor in Class A operation to generate an output signal of the Class A amplifier circuit.

According to an embodiment, the output pin of the operational amplifier may be unutilized in the Class A amplifier circuit.

According to an embodiment, the first amplification stage may further comprise: a first DC servo sub-circuit configured to reduce DC offsets in the internal signal, the first DC servo sub-circuit including a second operational amplifier having: a first input terminal connected to an output node of the discrete transistor in the second amplification stage; a second input terminal connected to a ground node or a reference potential; and a first output terminal connected to a second compensation pin of the operational amplifier in the first amplification stage, the second compensation pin being originally intended for offset voltage compensation, wherein the first DC servo sub-circuit is configured to provide a corrective voltage to the second compensation pin, thereby reducing the DC offsets in the internal signal.

According to an embodiment, the first amplification stage may further comprise: a second DC servo sub-circuit configured to reduce DC offsets in an input signal to the operational amplifier, the second DC servo sub-circuit including a third operational amplifier having: a third input terminal connected to one of input pins of the operational amplifier in the first amplification stage; a fourth input terminal connected to a further ground node or a further reference potential; and an second output terminal connected to the one of input pins of the operational amplifier in the first amplification stage, wherein the second DC servo sub-circuit is configured to provide a corrective voltage to an input pin of the operational amplifier, thereby reducing the DC offsets in the input signal.

According to an embodiment, the operational amplifier may further comprise a third compensation pin originally intended for offset trimming, the third compensation pin being connected to a further ground node through a resistor, the resistor being configured to stabilize voltage variations on the third compensation pin caused by feedback signals from the first DC servo sub-circuit.

According to an embodiment, the operational amplifier may be configured as an inverting amplifier, an input signal of the operational amplifier being connected to an inverting input of the operational amplifier through an input resistor, and a feedback resistor being connected between the inverting input and an output node of the discrete transistor in the second amplification stage.

According to an embodiment, the operational amplifier may be configured to accept balanced input signals, a positive input signal of the operational amplifier being connected to a non-inverting input of the operational amplifier through a positive input resistor, and a negative input signal of the operational amplifier being connected to an inverting input of the operational amplifier through a negative input resistor.

According to an embodiment, the discrete transistor in the second amplification stage may be a NPN bipolar junction transistor (BJT) configured as an emitter follower, an emitter of the NPN BJT being connected to an output of the second amplification stage, a base of the NPN BJT being connected to the first compensation pin of the operational amplifier in the first amplification stage, and a collector of the NPN BJT being connected to a positive supply voltage.

According to an embodiment, the discrete transistor in the second amplification stage may be a PNP BJT configured as an emitter follower, an emitter of the PNP BJT being connected to an output of the second amplification stage, a base of the PNP BJT being connected to the first compensation pin of the operational amplifier in the first amplification stage, and a collector of the PNP BJT being connected to a negative supply voltage.

According to an embodiment, the discrete transistor in the second amplification stage may be a Metal-Oxide-Semiconductor Field Effect Transistor (MOSFET) configured as a source follower, a drain of the MOSFET being connected to an output of the second amplification stage, a gate of the MOSFET being connected to the first compensation pin of the operational amplifier in the first amplification stage, and a source of the MOSFET being connected to a negative supply voltage.

According to an embodiment, the discrete transistor in the second amplification stage may be a junction field-effect transistor (JFET) configured as a source follower, a gate of the JFET being connected to the first compensation pin of the operational amplifier, a source of the JFET being connected to an output of the second amplification stage, and a drain of the JFET being connected to a positive supply voltage.

According to an embodiment, the second amplification stage may comprise a current stabilization sub-circuit for maintaining a consistent operating point of the discrete transistor.

According to an embodiment, the current stabilization sub-circuit may be configured as one of: a constant current source, a constant current sink, a Wilson current mirror, or a Widlar current source.

In another aspect, the present disclosure provides a method of operating a Class A amplifier circuit, the method comprising: feeding an input signal to an operational amplifier of a first amplification stage, the operational amplifier having an output pin and a first compensation pin, the output pin being configured to output an amplified signal through a Class A/B output stage, and the first compensation pin, originally intended for internal frequency response adjustment, being repurposed to provide an internal signal prior to the Class A/B output stage; amplifying the input signal by the operational amplifier in Class A operation to generate the internal signal; outputting the internal signal from the first compensation pin of the operational amplifier to a discrete transistor of a second amplification stage; and amplifying the internal signal by the discrete transistor in Class A operation to generate an output signal of the Class A amplifier circuit.

According to an embodiment, the method may further comprise: applying a corrective voltage to the second compensation pin to reduce DC offsets in the internal signal using a first DC servo sub-circuit, the first DC servo sub-circuit including a second operational amplifier having: a first input terminal connected to an output node of the discrete transistor in the second amplification stage; a second input terminal connected to a ground node or a reference potential; and a first output terminal connected to a second compensation pin of the operational amplifier in the first amplification stage, the second compensation pin being originally intended for offset voltage compensation.

According to an embodiment, the method may further comprise: applying a corrective voltage to an input pin of the operational amplifier to reduce DC offsets in the input signal to the operational amplifier using a second DC servo sub-circuit, the second DC servo sub-circuit including a third operational amplifier having: a third input terminal connected to one of the input pins of the operational amplifier in the first amplification stage; a fourth input terminal connected to a further ground node or a further reference potential; and a second output terminal connected to the one of the input pins of the operational amplifier in the first amplification stage.

According to an embodiment, the method may further comprise: stabilizing voltage variations on a third compensation pin of the operational amplifier caused by feedback signals from the first DC servo sub-circuit using a resistor, the third compensation pin being connected to a further ground node through the resistor, the third compensation pin being originally intended for offset trimming.

According to an embodiment, the discrete transistor in the second amplification stage may be a NPN bipolar junction transistor (BJT) configured as an emitter follower, an emitter of the NPN BJT being connected to an output of the second amplification stage, a base of the NPN BJT being connected to the first compensation pin of the operational amplifier in the first amplification stage, and a collector of the NPN BJT being connected to a positive supply voltage; or wherein the discrete transistor in the second amplification stage is a PNP BJT configured as an emitter follower, an emitter of the PNP BJT being connected to an output of the second amplification stage, a base of the PNP BJT being connected to the first compensation pin of the operational amplifier in the first amplification stage, and a collector of the PNP BJT being connected to a negative supply voltage.

According to an embodiment, the discrete transistor in the second amplification stage may be a Metal-Oxide-Semiconductor Field Effect Transistor (MOSFET) configured as a source follower, a drain of the MOSFET being connected to an output of the second amplification stage, a gate of the MOSFET being connected to the first compensation pin of the operational amplifier in the first amplification stage, and a source of the MOSFET being connected to a negative supply voltage; or wherein the discrete transistor in the second amplification stage is a junction field-effect transistor (JFET) configured as a source follower, a gate of the JFET being connected to the first compensation pin of the operational amplifier, a source of the JFET being connected to an output of the second amplification stage, and a drain of the JFET being connected to a positive supply voltage.

According to an embodiment, the method may further comprise: maintaining a consistent operating point of the discrete transistor in the second amplification stage using a current stabilization sub-circuit.

Other aspects and features of the present invention will become apparent to those of ordinary skill in the art upon review of the following description of specific embodiments of the invention in conjunction with the accompanying claims.

### BRIEF DESCRIPTION OF THE DRAWINGS

In drawings which illustrate embodiments of the disclosure,

FIG. 1 shows an example configuration of an audio amplifier circuit according to a first implementation of the present disclosure.

FIG. 2 shows an example configuration of an audio amplifier circuit according to a second implementation of the present disclosure.

FIG. 3 shows an example configuration of an audio amplifier circuit according to a third implementation of the present disclosure.

FIG. 4 shows an example configuration of an audio amplifier circuit according to a fourth implementation of the present disclosure.

FIG. 5 shows an example configuration of an audio amplifier circuit according to a fifth implementation of the present disclosure.

FIG. 6 shows an example configuration of an audio amplifier circuit according to a sixth implementation of the present disclosure.

FIG. 7 shows an example configuration of an audio amplifier circuit according to a seventh implementation of the present disclosure.

FIG. 8 shows an example configuration of an audio amplifier circuit according to an eighth implementation of the present disclosure.

FIG. 9 shows an example configuration of an audio amplifier circuit according to a ninth implementation of the present disclosure.

FIG. 10 shows an example configuration of an audio amplifier circuit according to a tenth implementation of the present disclosure.

### DETAILED DESCRIPTION

In the context of the present disclosure, various terms are used in accordance with what is understood to be the ordinary meaning of those terms.

Operational amplifiers (op-amps) have become an integral part of audio amplification systems due to their versatility, precision, and compact design. Their integration into modern audio circuits enables consistent performance over a wide range of operating conditions. However, the choice of amplifier topology has a significant impact on overall audio quality, particularly in applications that require high fidelity.

Among the various classes of amplifiers, Class A amplification is recognized for its ability to produce linear and distortion-free amplification. In Class A operation, the amplifier device conducts current continuously throughout the entire input signal cycle, avoiding the switching transitions inherent in Class A/B and other configurations. This continuous operation ensures minimal waveform discontinuities, a feature highly valued by those who value tonal accuracy and transparency in sound reproduction. As a result, Class A amplification is often considered for achieving higher audio fidelity.

Despite their advantages, traditional Class A amplifiers face certain challenges that limit their widespread adoption. A primary concern is efficiency, as continuous current conduction results in significant power dissipation, even in the absence of an input signal. This inherent inefficiency often requires larger heat sinks and power supplies, increasing the cost and size of the overall system. In addition, traditional Class A designs often rely on discrete active components, which can introduce variability due to component mismatch, require careful tuning, and increase manufacturing complexity.

Another consideration in Class A designs is the susceptibility to thermal drift. Continuous operation of the output stage generates heat that can affect the characteristics of nearby components, including input stages and bias circuits. This thermal coupling can introduce subtle distortion or noise, especially when the amplifier is subjected to dynamic changes in signal levels. Various techniques have been used to address these issues, such as thermal compensation circuits and precision matching of components. However, these solutions can increase design complexity and cost.

The present disclosure achieves the desirable characteristics of Class A operation, such as minimal distortion and linearity, while addressing the inefficiencies and challenges associated with traditional implementations. The disclosed audio amplifier circuit utilizes innovative methods of utilizing integrated circuit operational amplifiers combined with external output stages to provide the benefits of Class A operation in a manner that mitigates the drawbacks of conventional designs. These methods aim to improve thermal stability, reduce distortion, and achieve low-cost manufacturability without compromising audio quality.

The following examples illustrate various aspects of the invention, demonstrating specific configurations and operational scenarios under which the disclosed audio amplifier circuit may be implemented. These examples highlight conditions for achieving Class A operation using the compensation pin of an operational amplifier in conjunction with a discrete output stage, as well as configurations for mitigating distortion, thermal modulation, and DC offset issues. Selected examples are illustrative of advantages that may be obtained compared to alternative methods, including reduced crossover distortion, enhanced thermal stability, and improved signal fidelity. These advantages are accordingly illustrative of particular embodiments and are not necessarily indicative of the characteristics of all aspects of the invention.

As used herein, the term “about” refers to an approximately +/−10% variation from a given value. It is to be understood that such a variation is always included in any given value provided herein, whether or not it is specifically referred to.

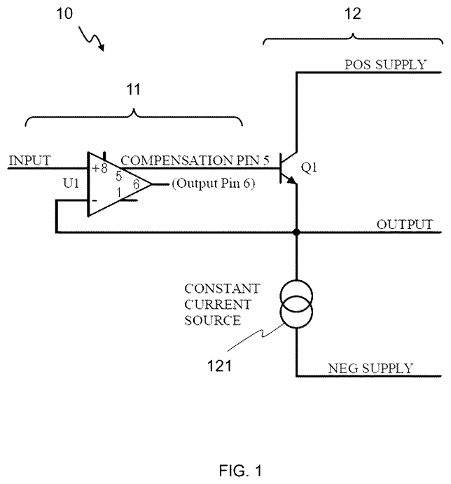

FIG. 1 illustrates a schematic diagram of a first implementation of an audio amplifier circuit 10. The circuit includes a first amplification stage 11 comprising an op-amp U1, which is configured to operate in a manner distinct from its conventional usage. In this configuration, the op-amp's compensation pin (pin 5) is utilized as an output, bypassing the standard output pin (pin 6) typically associated with Class A/B operation. The compensation pin provides access to an internal signal preceding the Class A/B output stage of the op-amp, enabling the circuit to maintain Class A operation.

In conventional designs, pin 5 of the op-amp is generally reserved for compensation purposes, such as adjusting bandwidth or slew rate, by connecting external components like capacitors or resistors. In most applications, this pin is left unused or designated as “no connection” in data sheets. However, in the present disclosure, pin 5 is repurposed as a low-current output tap, allowing a Class A signal to be extracted before the Class A/B output stage. Meanwhile, the intended output pin 6 is left unused.

Additionally, the op-amp U1 includes other pins, such as pins 1 and 8, which are commonly associated with compensation adjustments in certain op-amp designs, including the 5534 series. These pins are typically used in conjunction with external trimmer resistors to fine-tune offset voltages or improve device stability. In the present circuit, these pins may remain unused or serve secondary functions, depending on the implementation. However, the ability to repurpose these pins for alternative uses, such as integrating DC servo mechanisms or improving thermal stability, which will be described in relation to other implementations, demonstrates the flexibility of the described configuration. This versatility is advantageous in audio applications where precision and adaptability are desired.

The signal from pin 5 is connected to a second amplification stage 12 comprising a discrete transistor Q1 configured as a common emitter. In this embodiment, Q1 is an NPN bipolar junction transistor (BJT), although alternative configurations, such as a PNP BJT or a field-effect transistor (FET), may be used depending on specific design requirements.

To ensure linearity in the second amplification stage 12, the emitter of Q1 is connected to a constant current source 121 used as a current stabilization sub-circuit. The constant current source 121 stabilizes the operating point of Q1 by maintaining a consistent current flow through the transistor, regardless of variations in the input signal or supply voltage. The collector of Q1 is connected to a “POS SUPPLY”, which provides the positive supply voltage, while its emitter is also connected to an “OUTPUT” node where the amplified signal is available. The constant current source 121 is connected between the emitter of Q1 and a “NEG SUPPLY”, which provides the negative supply voltage, facilitating proper biasing of Q1.

The operational amplifier U1, in the first amplification stage 11, receives an input signal at its non-inverting input (+). Its inverting input (−) can be configured for feedback or connected to a resistor network to reduce feedback and thus increase a gain of the circuit (in this example, the inverting input is connected to the emitter of Q1 for near unity gain). Pin 5 of U1 is connected to the base of Q1.

The use of discrete components, such as the transistor Q1, in the second amplification stage 12 provides several advantages. Firstly, Q1 is suitable to drive the output, so as to reduce the thermal load on the operational amplifier U1. Since U1 is a relatively small IC package, its internal components are more susceptible to temperature fluctuations when driving loads directly. By delegating the output drive function to Q1, the circuit reduces thermal variations within U1, thereby maintaining its stability. Additionally, because Q1 is not subjected to a demanding load, excessive heat generation in the output stage is unlikely, further reducing thermal coupling effects. This configuration enhances signal fidelity by mitigating distortions associated with temperature-induced variations in U1.

The combination of the op-amp's U1 internal gain and input stages with the discrete Class A output stage provides a balance between performance and manufacturability. The op-amp U1 contributes high gain, precision, and reduced device variability due to features like laser trimming during manufacturing. In contrast, the discrete output stage ensures that Class A operation can be preserved throughout the amplifier circuit.

An additional benefit of utilizing pin 5 is the avoidance of zero-cross distortion. In conventional Class A/B operation, as seen with pin 6, distortion arises at the zero-crossing point of the waveform due to switching between devices. By using pin 5, the circuit bypasses the originally intended output stage entirely so as to maintain a continuous Class A signal flow.

The 5534 series of op-amps, including the NE 5534, SA 5534, and SE 5534 variants, are examples of suitable op-amps that include a pin 5 compensation feature, enabling the functionality described herein. These op-amps are commonly used for their low noise and high linearity in audio applications. Additionally, the AD744 op-amp, which also features a compensation pin, may be used in similar configurations, although it may exhibit different noise characteristics compared to the 5534 series.

It should be understood that the present disclosure is not limited to the specific models mentioned. Other types of operational amplifiers may also serve as the op-amp U1, provided they include an accessible internal stage that allows for Class A output operation via a compensation pin or an equivalent feature. Such op-amps need not be restricted to the exact internal architecture or pin configuration of the 5534 series, as advancements in semiconductor design may introduce alternative configurations or labeling conventions.

Furthermore, while the terms “pin 5” and “pin 6” are used herein for descriptive purposes based on the industry-standard labeling of the 5534 series and similar op-amps, the present disclosure does not intend to limit the invention to this specific nomenclature. Future generations of op-amps may employ different labels, numbering, or structures to describe equivalent functionalities. As such, the present disclosure should be interpreted to encompass op-amps with equivalent features, regardless of specific labeling conventions or package designs.

While FIG. 1 illustrates various components of the amplifier circuit in a simple form, variations of the circuit may include additional features, such as DC servo circuits for offset correction or alternative current stabilization sub-circuit configurations, which will be described in the following.

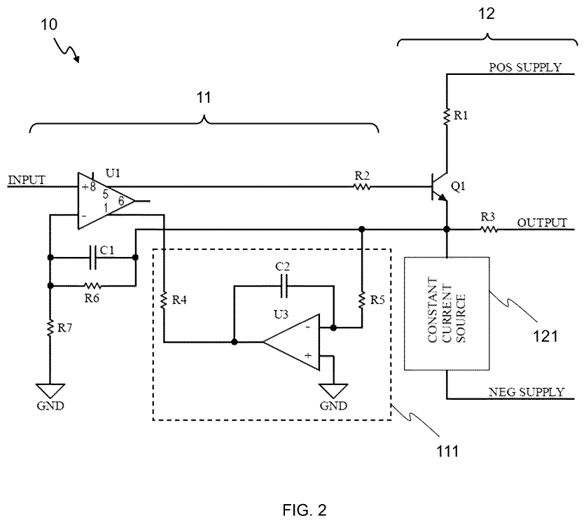

FIG. 2 illustrates a schematic diagram of a second implementation of the audio amplifier circuit 10, representing a variation of the amplifier configuration depicted in FIG. 1. This circuit includes a first amplification stage 11, a second amplification stage 12, and a DC servo sub-circuit 111 to address output DC offsets.

The first amplification stage 11 comprises an op-amp U1, configured such that its compensation pin (pin 5) serves as a Class A output, bypassing the conventional output pin (pin 6). Pin 1, another compensation pin of U1, is connected to the DC servo circuit 111, which provides a corrective voltage to reduce or eliminate output DC offsets. The main input signal is supplied to the non-inverting input (+) of U1, while the inverting input (−) is part of the gain configuration formed by resistors R6 and R7.

The DC servo sub-circuit 111 includes a second op-amp U3, resistors R4 and R5, and a capacitor C2. The inverting input (−) of U3 is connected to the emitter of transistor Q1 through resistor R5, so that the DC servo monitors the DC component of the output signal from Q1. The non-inverting input (+) of U3 is grounded. Capacitor C2, placed in parallel with the feedback path of U3, along with resistors R4 and R5, forms an integrator that responds to slow-changing DC offsets while ignoring the high-frequency AC components of the signal. The output of U3 is fed back to pin 1 of U1 through resistor R4, influencing the internal biasing of U1 without disturbing the primary signal amplification path.

Resistors R6 and R7 in the first amplification stage 11 determine the voltage gain of U1, with the gain ratio set by R6/R7 (R6 and R7 are connected to the inverting input of U1 on one side and to the emitter of Q1 and ground, respectively, on the other side). Capacitor C1, connected in parallel with R6, allows for adjustment of the frequency response to enable the circuit to be tailored to specific audio applications. This ensures the amplifier achieves a desirable balance between gain and frequency characteristics.

The second amplification stage 12 includes a discrete transistor Q1, configured as an emitter follower, and additional components, including resistors R1, R2, and R3, and a constant current source 121 used as a current stabilization sub-circuit. The base of Q1 receives the output signal of the first amplification stage 11 via resistor R2, which serves to limit the base current and provide impedance matching. The collector of Q1 is connected to the positive supply voltage (“POS SUPPLY”). Resistor R3 is connected between the emitter of Q1 and the “OUTPUT” node to control the emitter current and provide impedance matching with subsequent stages or loads.

The constant current source 121 is connected to the emitter of Q1 and to the negative supply voltage (“NEG SUPPLY”). It stabilizes the emitter current of Q1 to facilitate a consistent operating point even under varying input signal levels or load conditions. This configuration reduces signal distortion and enhances the linearity of the output.

Typically, the “POS SUPPLY” represents a positive voltage source (e.g., +15V), while the “NEG SUPPLY” represents a negative voltage source (e.g., −15V), enabling bipolar operation of the circuit. The “OUTPUT” node provides the amplified signal for further use, such as driving speakers or external devices.

The inclusion of the DC servo circuit eliminates the need for large coupling capacitors traditionally used to block DC components at the output. Coupling capacitors can introduce undesirable phase shifts and distortions at low frequencies, as well as increase the cost and size of the circuit. By addressing DC offsets directly at their source, the circuit maintains a compact design while preserving high-fidelity audio performance.

Like the first implementation described in relation to FIG. 1, the use of discrete components in the second amplification stage 12 provides thermal isolation from U1, reducing thermal modulation effects and facilitating consistent performance.

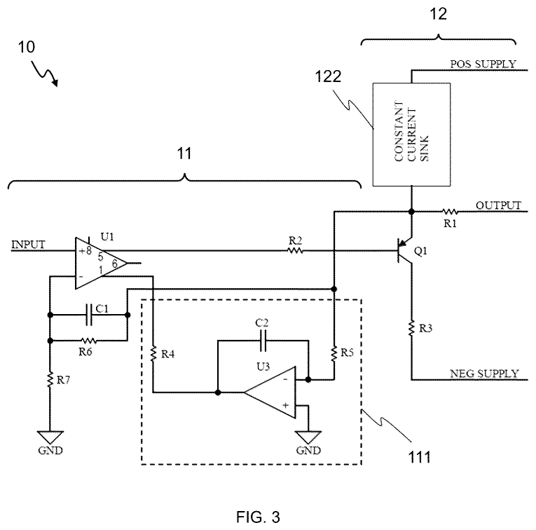

FIG. 3 illustrates a schematic diagram of a third implementation of the audio amplifier circuit 10, representing a variation of the second implementation depicted in FIG. 2. This circuit includes a first amplification stage 11, a second amplification stage 12, and a DC servo sub-circuit 111 to mitigate output DC offsets.

The first amplification stage 11 in the third implementation is identical to the one described in relation to FIG. 2. It comprises an op-amp U1 configured such that its compensation pin (pin 5) serves as a Class A output, bypassing the conventional output pin (pin 6). Similarly, the DC servo sub-circuit 111, connected to pin 1 of U1, monitors and adjusts DC offsets by applying a correction voltage to pin 1. The structure and operation of the DC servo sub-circuit 111, which includes resistors R4 and R5, capacitor C2, and the second op-amp U3, are the same as described in FIG. 2. This configuration ensures that the output signal is free or nearly free of DC offsets while maintaining the integrity of the primary amplification path.

The second amplification stage 12 in the third implementation differs from the configuration in FIG. 2 primarily in its use of a PNP transistor, Q1, configured as an emitter follower. An emitter follower, also known as a common collector amplifier, provides current amplification with unity voltage gain, meaning the output voltage closely follows the input voltage. In this implementation, Q1 is a PNP transistor, as opposed to the NPN transistor used in FIG. 2. The use of a PNP transistor may provide design flexibility depending on the desired polarity of the output signal or other circuit-specific considerations.

In the second amplification stage 12, the base of Q1 is connected to the output of the first amplification stage 11 through resistor R2, which limits the base current and provides impedance matching. The collector of Q1 is connected to the negative supply voltage (“NEG SUPPLY”) through resistor R3, in contrast to the NPN configuration in FIG. 2, where the collector is connected to the positive supply voltage. This reversed configuration aligns with the characteristics of a PNP transistor.

The emitter of Q1 serves as the primary output node for the second amplification stage 12 and is connected to the “OUTPUT” node. Resistor R1, connected in series between the emitter of Q1 and the “OUTPUT” node, regulates the emitter current and provides impedance matching for subsequent stages or loads.

Additionally, the emitter of Q1 is connected to a constant current sink 122 used as a current stabilization sub-circuit, which is in turn connected to the positive supply voltage (“POS SUPPLY”). The constant current sink 122 stabilizes the emitter current of Q1, facilitating consistent operation under varying input signal levels or load conditions. A constant current sink (such as the one described in relation to FIG. 3) operates similarly to a constant current source (such as the ones described in relation to FIGS. 1 and 2) but is designed to sink current instead of sourcing it.

Typically, the “POS SUPPLY” corresponds to a positive voltage (e.g., +15V), and the “NEG SUPPLY” corresponds to a negative voltage (e.g., −15V), enabling bipolar operation of the circuit. The “OUTPUT” node provides the amplified signal for further use, such as driving speakers or external devices.

The use of a PNP transistor in this implementation introduces a design alternative that may be advantageous in certain applications. For instance, the PNP configuration may be used in circuits where the output stage needs to source current rather than sink it, or where the polarity of the power supplies dictates the use of PNP devices.

As in the previous implementations, the thermal isolation provided by the use of discrete components in the second amplification stage 12 helps reduce thermal modulation effects, facilitating consistent performance. The combination of integrated and discrete components achieves a balance between performance, manufacturability, and cost, making the circuit suitable for high-fidelity audio applications.

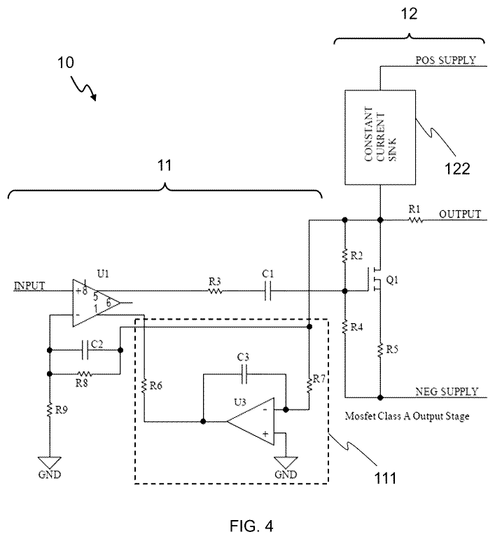

FIG. 4 illustrates a schematic diagram of a fourth implementation of the audio amplifier circuit 10, representing a further variation of the amplifier configuration described in FIG. 3. The circuit includes a first amplification stage 11, a second amplification stage 12, and a DC servo sub-circuit 111 to address output DC offsets. This implementation introduces a MOSFET transistor, Q1, configured as a source follower in the second amplification stage 12.

The first amplification stage 11 is structurally and functionally identical to the first amplification stages described in FIGS. 2 and 3, except for the labeling of the resistors and capacitors to account for additional components in other parts of the circuit. This stage includes the op-amp U1, which utilizes its compensation pin (pin 5) as a Class A output, bypassing the conventional output pin (pin 6). Pin 1, another compensation pin, is connected to the DC servo circuit 111, which monitors and adjusts DC offsets in the output. The voltage gain of this stage is determined by the ratio of resistors R8 and R9, with capacitor C2 influencing the frequency response of the circuit. The structure and operation of the DC servo sub-circuit 111, which includes resistors R6 and R7, capacitor C3, and the second op-amp U3, are the same as described in FIGS. 2 and 3. This configuration ensures that the output signal is free or nearly free of DC offsets while maintaining the integrity of the primary amplification path.

The second amplification stage 12 differs from the third implementations described in relation to FIG. 3 in that this implementation uses a MOSFET transistor Q1, configured as a source follower, instead of a BJT configured as an emitter follower. A source follower, also known as a common drain amplifier, provides current amplification with unity voltage gain, meaning the output voltage follows the input voltage. MOSFETs, or metal-oxide-semiconductor field-effect transistors, are advantageous in this configuration due to their high input impedance, which reduces loading on the preceding stage, and their fast switching characteristics, which enhance high-frequency performance.

In this implementation, the gate of Q1 receives the output signal from the first amplification stage 11 through coupling capacitor C1 and resistor R3. Capacitor C1 blocks DC components from the pin 5 of the op-amp U1. Resistor R3 limits the gate current and provides impedance matching.

The source of Q1 is connected to the negative supply voltage (“NEG SUPPLY”) through resistor R5. The drain of Q1 is connected to the “OUTPUT” node through resistor R1, which regulates the source current and providing impedance matching for the connected load.

A constant current sink 122 used as a current stabilization sub-circuit is connected between the drain of Q1 and the positive supply voltage (“POS SUPPLY”). This sink facilitates a stable operating point for Q1 by maintaining a consistent current flow through the MOSFET, regardless of variations in input signal levels or load conditions. In other words, the constant current sink 122 can stabilize the MOSFET's operating point by providing a consistent drain current, which reduces signal distortion and facilitates linear operation.

Resistor R2 is connected between the gate of Q1 and the drain of Q1. Resistor R2 serves to stabilize the input to the gate of Q1 and prevent oscillations, which may occur due to the high input impedance of MOSFETs. Additionally, resistor R4 is connected between the gate of Q1 and the “NEG SUPPLY” to facilitate proper biasing of the MOSFET and prevent unwanted voltage drift at the gate.

The second amplification stage 12, with its MOSFET-based source follower configuration, introduces specific advantages. The relatively high input impedance of the MOSFET reduces the loading effect on the first amplification stage 11, preserving the integrity of the signal. Additionally, the source follower configuration provides a relatively low output impedance, which may be suitable for driving low-impedance loads or interfacing with capacitive elements in subsequent stages.

Similar to the previous implementations, the “POS SUPPLY” represents a positive voltage source (e.g., +15V), while the “NEG SUPPLY” represents a negative voltage source (e.g., −15V). The “OUTPUT” node provides the amplified signal for further use.

As in the previous implementations, the thermal isolation provided by the use of discrete components in the second amplification stage 12 helps reduce thermal modulation effects, facilitating consistent performance. The combination of integrated and discrete components achieves a balance between performance, manufacturability, and cost, making the circuit suitable for high-fidelity audio applications.

The choice of transistor type (NPN, PNP, or MOSFET) allows for customization of the circuit to meet specific application requirements. For example, the use of a MOSFET may be preferred in scenarios where high input impedance or fast switching performance is desired.

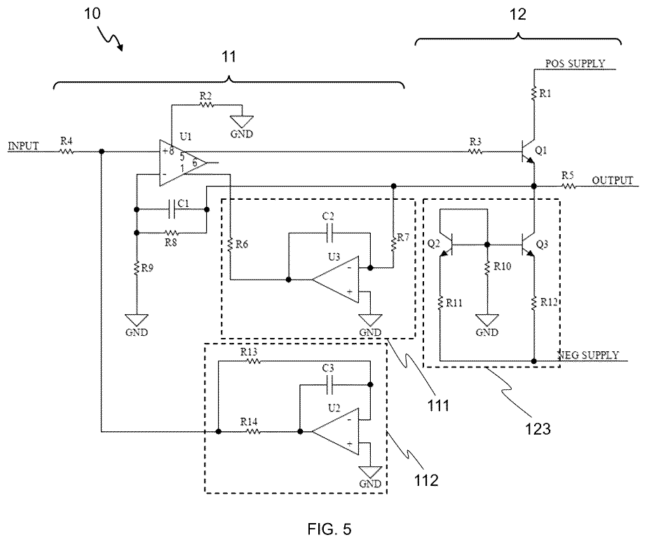

FIG. 5 illustrates a schematic diagram of a fifth implementation of the audio amplifier circuit 10, representing a further variation of the amplifier configuration described in FIG. 2. This configuration incorporates a first amplification stage 11, a second amplification stage 12, and two DC servo sub-circuits 111 and 112. The inclusion of a second DC servo sub-circuit 112 enables the reduction of input DC offsets, which further enhances the overall performance of the amplifier.

The first amplification stage 11 is structurally and functionally similar to the implementations described in FIG. 2, with additional components incorporated to accommodate the second DC servo sub-circuit 112 and provide compensation for pin 8 of op-amp U1. U1 utilizes its compensation pin (pin 5) as a Class A output, bypassing the conventional output pin (pin 6). The voltage gain is determined by the ratio of resistors R8 and R9, with capacitor C1 connected in parallel with R8 to influence the frequency response of the circuit.

The second DC servo sub-circuit 112 comprises a third op-amp U2, resistors R13 and R14, and capacitor C3. The purpose of this sub-circuit is to reduce input DC offsets at the non-inverting input of U1. Input DC offsets may originate from sources such as mismatched input impedances or DC leakage through switches and variable resistors, potentially resulting in undesirable audio artifacts like clicks, pops, or scratches.

In this implementation, the inverting input (−) of U2 is connected to the non-inverting input (+) of U1 through resistor R13, allowing the second DC servo sub-circuit 112 to monitor the DC component of the input signal. The non-inverting input (+) of U2 is grounded, providing a stable reference point. Capacitor C3, placed in parallel with the feedback path of U2, creates an integrator configuration with resistor R14. This integrative behavior ensures that the second DC servo sub-circuit 112 focuses on slow-changing or steady-state DC offsets while ignoring the high-frequency AC components of the signal.

The output of U2 is connected back to the non-inverting input (+) of U1, allowing the second DC servo sub-circuit 112 to apply a correction voltage that reduces input DC offsets. By addressing DC offsets directly at the input, the circuit may not need for DC-blocking capacitors that are conventionally used for this purpose. This approach preserves signal integrity, reduces phase distortion, and maintains a compact circuit design.

The first DC servo sub-circuit 111 is identical to the implementations described in FIGS. 2-4. It comprises an op-amp U3, resistors R6 and R7, and capacitor C2. The first DC servo sub-circuit 111 monitors and adjusts output DC offsets by applying a correction voltage to pin 1 of U1, which is internally connected to the differential input stage of U1. This ensures that the output signal remains free or nearly free of DC offsets without interfering with the primary signal amplification path.

In this implementation, pin 8 of U1 is grounded through resistor R2. Pin 8, along with pin 1, is traditionally used in op-amp designs for offset adjustment using a trimmer potentiometer. However, in the present disclosure, resistor R2 is used to compensate for the variable voltage at pin 1 introduced by the first DC servo sub-circuit 111. This configuration may increase the range of output DC offsets that can be corrected by the first DC servo sub-circuit 111, further improving its effectiveness.

The second amplification stage 12 includes a discrete transistor Q1, configured as an emitter follower. In this implementation, the base of Q1 receives the output signal from the first amplification stage 11 through resistor R3, which serves to limit the base current and provide impedance matching. The collector of Q1 is connected to the positive supply voltage (“POS SUPPLY”) through resistor R1, while its emitter is connected to the output node through resistor R5. The second amplification stage 12 also includes a modified Widlar current mirror sub-circuit 123 used as a current stabilization sub-circuit, which includes transistors Q2 and Q3 and resistors R10, R11, and R12. The modified Widlar current mirror sub-circuit 123 serves to provide a stable and precise current source for Q1, so that consistent operation and linearity in the output stage can be provided. The conventional Widlar current source generally would tie the emitter of Q2 directly to the negative power supply. This variation introduces a resistor R11 between the emitter of Q2 and the negative supply which serves to increase the current gain of the sub-circuit and allows for a higher resistance value for R10. The values of R10, R11 and R12 affect output current.

In the Widlar current source sub-circuit 123, Q2 and Q3 are arranged such that the collector of Q2 is connected to both the base of Q2 and the base of Q3, and the emitter of Q3 is connected to the negative supply voltage (“NEG SUPPLY”) through resistor R12. The emitter of Q2 is also connected to the “NEG SUPPLY” through resistor R11. The collector of Q3 is connected to the emitter of Q1, forming the current-sinking path for the emitter current of Q1. The base of Q2 and the base on Q3 are grounded through resistor R10, which due to the voltage potential between ground and the node formed by R10, Q2 and Q3 sets an initial current which would be mirrored except for the inclusion of R11 which sets current gain.

The primary purpose of the Widlar current source sub-circuit 123 is to stabilize the emitter current of Q1, facilitating consistent operation under varying input signal levels or load conditions. By maintaining a constant current, the Widlar current source sub-circuit 123 enhances the linearity of the output signal and reduces distortion introduced by variations in the load.

The Widlar current source sub-circuit 123 provides improved output impedance and current regulation by utilizing the feedback between Q2 and Q3. This configuration compensates for small variations in the supply voltage or temperature changes, ensuring that the emitter current of Q1 remains stable. This feature makes it suitable for high-fidelity audio applications, where accurate and stable operation is desired.

Similar to the previous implementations, the “POS SUPPLY” represents a positive voltage source (e.g., +15V), while the “NEG SUPPLY” represents a negative voltage source (e.g., −15V). The “OUTPUT” node provides the amplified signal for further use.

As in the previous implementations, the thermal isolation provided by the use of discrete components in the second amplification stage 12 helps reduce thermal modulation effects, facilitating consistent performance. The combination of integrated and discrete components achieves a balance between performance, manufacturability, and cost, making the circuit suitable for high-fidelity audio applications.

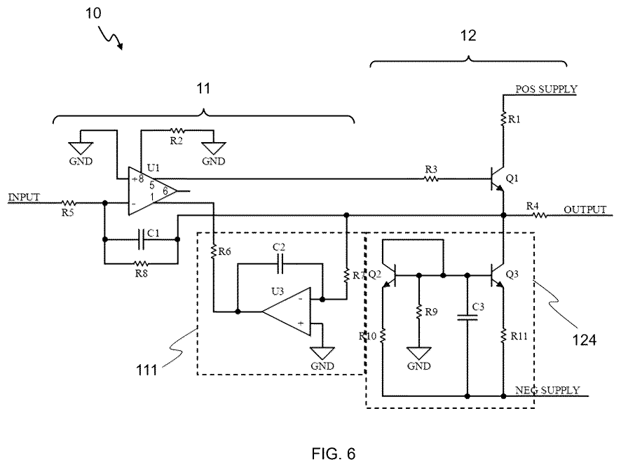

FIG. 6 illustrates a schematic diagram of a sixth implementation of the audio amplifier circuit 10. This configuration is similar in certain respects to the implementations described in relation to FIG. 5 but introduces an inverting amplifier configuration in the first amplification stage 11 and modified current stabilization in the second amplification stage 12.

The first amplification stage 11 comprises an op-amp U1, configured such that the input signal is connected to the inverting input (−) via resistor R5, while the non-inverting input (+) is grounded. This is distinct from the configurations described in FIGS. 1-5, where the non-inverting input received the input signal. The feedback network includes resistor R8 connected between the emitter of a discrete transistor Q1 in the second amplification stage and the inverting input (−) of U1, with capacitor C1 placed in parallel with R8. The gain of the first amplification stage 11 is determined by the ratio of R8 to R5, providing flexibility in configuring the amplifier for gain or attenuation as required.

Pin 5 of U1 continues to serve as a low-current output tap, bypassing the standard output pin (pin 6) and providing a Class A signal to drive the second amplification stage 12. As in earlier configurations, this repurposing of the compensation pin ensures Class A operation and avoids the distortion associated with conventional Class A/B designs.

A resistor R2 is connected between pin 8 of U1 and ground. Pin 8, associated internally with pin 1, is part of the differential pair within op-amp U1, and is used in the same way as R2 described in relation to FIG. 5.

The DC servo sub-circuit 111 remains similar to the one described in FIGS. 2-5 and thus serves the same purpose. It comprises a second op-amp U3, resistors R6 and R7, and capacitor C2. The inverting input (−) of U3 is connected to the emitter of Q1 through R7. The non-inverting input (+) of U3 is grounded. Capacitor C2 is connected in parallel with U3. The output of U3 is fed to pin 1 of U1. The inverting configuration of the first amplification stage 11 provides additional design flexibility.

The second amplification stage 12 comprises Q1, which configured as an emitter follower, and a second Widlar current source sub-circuit 124 used as a current stabilization sub-circuit, which includes transistors Q2 and Q3, capacitor C3, as well as resistors R9, R10, and R11. The emitter follower Q1 provides current amplification with unity voltage gain, ensuring that the amplified signal can drive subsequent stages or connected loads without significant distortion. The second Widlar current source sub-circuit 124 maintains a consistent current through Q1 under varying input signal levels and load conditions.

In this implementation, the base of Q1 receives the output signal from pin 5 of U1 through resistor R3, which limits the base current and provides impedance matching. The emitter of Q1 is connected to the “OUTPUT” node through resistor R4, which regulates the emitter current and provides impedance matching for subsequent stages. The collector of Q1 is connected to the positive supply voltage (“POS SUPPLY”) through resistor R1.

The second Widlar current source sub-circuit 124 is configured in the same way as the Widlar current source sub-circuit 123 described in relation to FIG. 5 for the same purpose. In addition, capacitor C3 is connected between the base of Q3 and the negative supply (“NEG SUPPLY”) to reduce noise caused by the difference between ground and the “NEG SUPPLY”. This also reduces AC differentials between the base and emitter of Q3.

The Widlar current source sub-circuit 124 includes three modifications that improve circuit performance while maintaining the basic function of a high-impedance current source. First, in a conventional Widlar current source, resistor R9 would typically be tied to the positive supply. However, in this implementation, R9 is instead referenced to ground. This may prevent noise from supply variations, as referencing to ground reduces the AC difference between the negative supply and ground, typically by half compared to tying R9 to the positive supply. This approach may also allow R9 to be a lower value, which helps reduce overall noise.

Second, capacitor C3 is introduced to shunt the reference node of the current source to the negative supply, forming a one-pole low-pass filter. This filtering may further reduce noise by attenuating high-frequency fluctuations at the current reference node. While the effect is relatively minor—given that the current source is inherently high impedance and negative feedback within the amplifier counteracts much of the noise—this modification may contribute to a cleaner overall signal. In practical applications, C3 may be typically used in higher-budget implementations where additional noise suppression is desirable.

Third, in a conventional Widlar current source, the emitter of Q2 is typically tied directly to a power rail. In this implementation, resistor R10 is added between the emitter of Q2 and the negative supply. This may increase the current gain of the current source and help optimize resistor values throughout the circuit, particularly keeping R11 and R9 at reasonably low values. The inclusion of R10 may allow for fine-tuning the current source parameters without significantly affecting the compliance voltage or stability of the circuit.

Similar to the previous implementations, the “POS SUPPLY” represents a positive voltage source (e.g., +15V), while the “NEG SUPPLY” represents a negative voltage source (e.g., −15V). The “OUTPUT” node provides the amplified signal for further use.

As in the previous implementations, the thermal isolation provided by the use of discrete components in the second amplification stage 12 helps reduce thermal modulation effects, facilitating consistent performance. The combination of integrated and discrete components achieves a balance between performance, manufacturability, and cost, making the circuit suitable for high-fidelity audio applications.

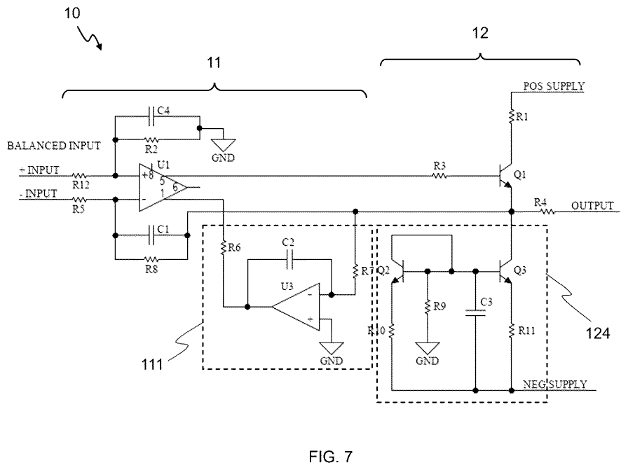

FIG. 7 illustrates a schematic diagram of a seventh implementation of the audio amplifier circuit 10 configured as a differential amplifier, adapted for balanced signal inputs. The configuration is similar to the amplifier circuit described in relation to FIG. 6, except for the input stage, which is designed to handle balanced signals.

The first amplification stage 11 in this implementation is designed to accept balanced input signals. The positive (+) input signal is provided to the non-inverting input (+) of op-amp U1 through resistor R12. Resistor R2 is connected between the non-inverting input (+) of U1 and ground, with capacitor C4 placed in parallel with R2. The negative (−) input signal is provided to the inverting input (−) of U1.

The remaining part of the circuit, including the second amplification stage 12, is identical to the configuration described in relation to FIG. 6. The signal from U1 is passed through resistors R3 to transistor Q1 in the second amplification stage, which is configured as an emitter follower. The second Wilson current mirror sub-circuit 124 provides a stable current source to stabilize the operating point of Q1 to facilitate linear operation.

The use of balanced inputs in this implementation provides advantages in rejecting common-mode noise and interference, particularly in applications where the signal is transmitted over long cables or in noisy environments. The differential amplifier configuration ensures that both positive and negative input signals are amplified with the same gain, thereby preserving the integrity of the input signal.

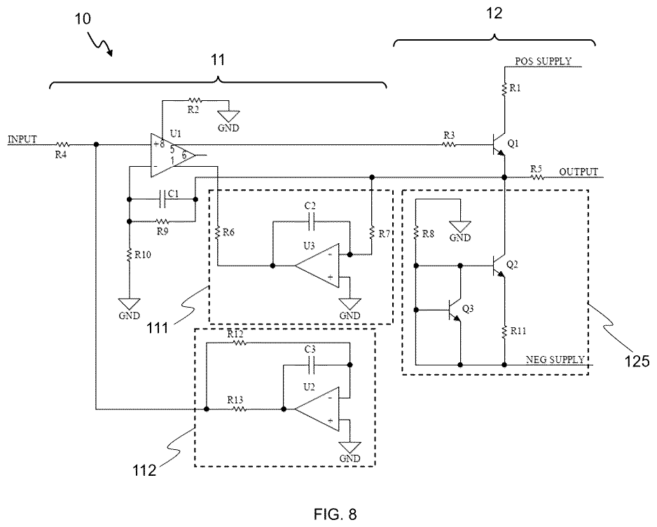

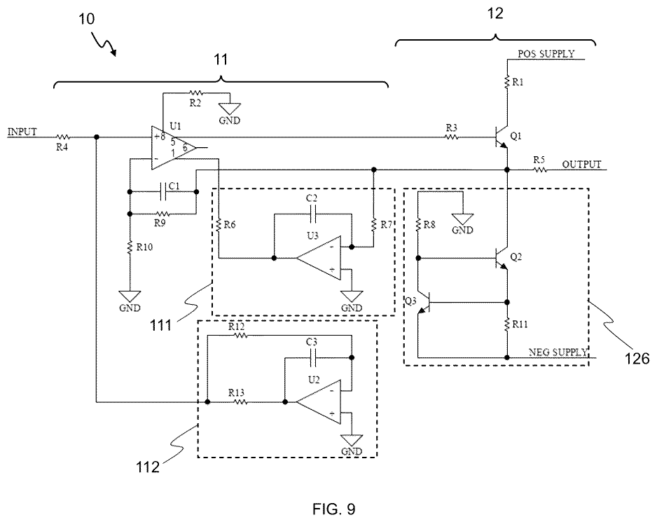

FIGS. 8 and 9 illustrates a schematic diagram of eighth and ninth implementations of the audio amplifier circuit 10, representing variations of the circuit described in relation to FIG. 5. The two implementations utilize an unmodified Widlar current source sub-circuit 125 in the second amplification stage 12 for current stabilization, thereby providing an alternative to the modified Widlar current mirror configuration described in relation to FIGS. 5-7. The rest of the components in this implementation, including the first amplification stage 11, the first DC servo sub-circuit 111, and the second DC servo sub-circuit 112, are identical to those described in relation to FIG. 5 and will not be repeated here.

A simple Widlar current source maintains a fixed output current while maintaining a high output impedance. In this implementation, the Widlar current source sub-circuit 125 provides stable current for transistor Q1 in the second amplification stage 12 to facilitate consistent operation and maintain the linearity of the output stage under varying load conditions and input signal levels.

As shown in FIG. 8, the Widlar current source sub-circuit 125 comprises transistors Q2 and Q3, along with resistors R8 and R11. The collector of Q2 is connected to the emitter of Q1. The emitter of Q2 is connected to resistor R11, which is then connected to the negative supply (“NEG SUPPLY”). The collector of Q3 is connected to the base of Q2. Transistor Q3 is connected with its base, collector, and collector tied together to the “NEG SUPPLY” and also grounded through R8.

As shown in FIG. 9, the Widlar current source sub-circuit 125 comprises transistors Q2 and Q3, along with resistors R8 and R11. The collector of Q2 is connected to the emitter of Q1. The emitter of Q2 is connected to resistor R11, which is then connected to the negative supply (“NEG SUPPLY”). The collector of Q3 is connected to the base of Q2 and is also grounded through R8. The base of Q3 is connected to the emitter of Q2. The emitter of Q3 is connected to the “NEG SUPPLY”.

In the two implementations shown by FIGS. 8 and 9, alternatively, the reference current controlled by R8 may be connected to the positive supply (“POS SUPPLY”) rather than being grounded. The Widlar current source is suitable for scenarios where reduced current output is required while maintaining sufficient compliance for voltage swings at the collector of Q2. Compared to a Wilson current source, which typically includes three or four bipolar junction transistors (BJTs) and provides increased output impedance and accuracy, the Widlar current source may offer a simpler solution that is sufficient for minimizing distortion while reducing the overall component count.

The inclusion of the basic Widlar current source sub-circuit 125 offers a design alternative to the modified Widlar current source sub-circuit described in relation to FIGS. 5-7. Various current source alternatives may be used if they can provide sufficient current and compliance in regards to voltage swing seen by the collector of Q2. These may include even simpler current sources based a pair of diodes or a zener used to bias Q2 or more complex current sources such as a Wilson Current Mirror. JFET or MOSFET based current sources are also feasible alternatives.

The current sources in the second amplification stage described herein can supply the necessary current to the emitter follower(s) needed to drive the expected load while also acting as a high impedance node. This high impedance characteristic ensures minimal loading on the emitter follower, thereby preserving the amplifier's near-ideal linearity and reducing distortion. The amount of current supplied can be set according to the anticipated external load or impedance of the destination that the amplifier will need to drive. This allows the circuit to optimize voltage swing while reducing current draw and heat dissipation, thus striking a balance between performance and efficiency.

Unlike passive resistive loading, which can introduce unwanted signal attenuation or variations in response due to supply fluctuations, the constant current sources according to the present disclosure can actively regulate the operating conditions of the emitter follower stage. By maintaining a steady operating point, it ensures that the amplifier retains consistent performance across varying signal levels, making it particularly beneficial for high-fidelity audio applications. The advantages extend beyond mere stabilization; by eliminating unnecessary variations in current flow, the current source allows the emitter follower to function with higher efficiency and precision, ultimately contributing to superior audio reproduction with reduced harmonic and intermodulation distortion.

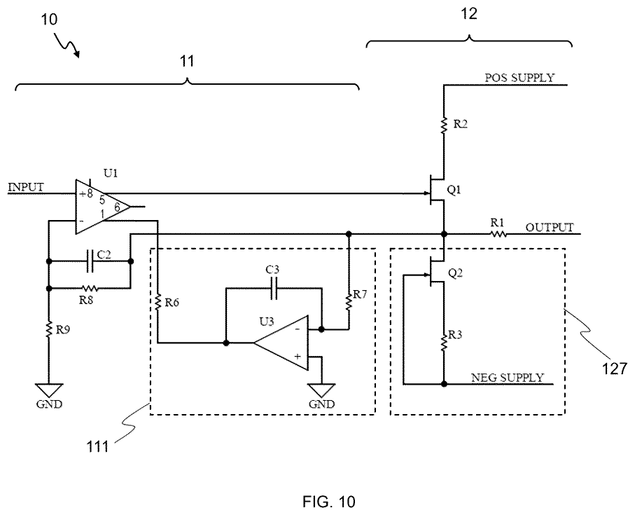

FIG. 10 illustrates a schematic diagram of a tenth implementation of the audio amplifier circuit 10, representing a variation of the amplifier configuration described in FIG. 2. This implementation differs from FIG. 2 primarily in the use of junction field-effect transistor (JFET) devices for both the source follower (Q1) in the second amplification stage 12 and the current stabilization sub-circuit 127. The rest of the components in this implementation, including the first amplification stage 11, are identical to those described in relation to FIG. 2 and will not be repeated here.

The gate of Q1 receives the output signal from pin 5 of U1. The source of Q1 is connected to the output node through resistor R1, which regulates the source current and provides impedance matching with the connected load. The drain of Q1 is connected to the positive supply voltage (“POS SUPPLY”) through R2, providing the necessary voltage for Q1's operation.

The current stabilization sub-circuit 127 comprises a JFET Q2 configured as a constant current source. The source of Q2 is connected to the negative supply voltage (“NEG SUPPLY”) through resistor R3, which determines the current output of the constant current source. The drain of Q2 is connected to the source of Q1, providing a stable current to the source follower. The gate of Q2 is connected to the “NEG SUPPLY”, thereby ensuring that Q2 operates in its saturation region, where it functions as a current source. This configuration provides a stable and precise current for the source follower.

The use of JFETs may introduce specific benefits. JFETs are inherently low-noise devices, making them suitable for high-fidelity audio applications. Their high input impedance reduces the loading effect on the preceding amplification stage, preserving the integrity of the signal. Additionally, the constant current source implemented with a JFET typically provides higher output impedance and better current regulation than simple BJT based current sources.

It should be understood that the implementations described herein are provided as illustrative examples, and are not intended to limit the scope of the disclosure. The specific configurations, components, and sub-circuits described in relation to the various figures are provided to demonstrate how the invention can be applied in practice. However, it is recognized that one skilled in the art can modify, adapt, or substitute these components and configurations without departing from the scope of the disclosure.

For example, different types of transistors (e.g., BJTs, MOSFETs, or JFETs) or alternative current stabilization techniques (e.g., Widlar current sources, Wilson current mirrors, or other constant current sources or sinks) may be employed depending on the specific design requirements, such as cost, performance, or manufacturing considerations. Furthermore, the specific resistor and capacitor values, as well as their placement in the circuit, may be adjusted or optimized based on the intended application or desired performance characteristics. These and other modifications are considered to fall within the scope of the disclosure as defined by the appended claims.

The terminology used herein is for the purpose of describing particular embodiments only and is not intended to be limiting. Accordingly, as used herein, the singular forms “a”, “an”, and “the” are intended to include the plural forms as well, unless the context clearly indicates otherwise. It will be further understood that the terms “comprises” and “comprising”, when used in this specification, specify the presence of one or more stated features, integers, steps, operations, elements, and components, but do not preclude the presence or addition of one or more other features, integers, steps, operations, elements, components, and groups. Directional terms such as “top”, “bottom”, “upwards”, “downwards”, “vertically”, and “laterally” are used in the following description for the purpose of providing relative reference only, and are not intended to suggest any limitations on how any article is to be positioned during use, or to be mounted in an assembly or relative to an environment. Additionally, the term “connect” and variants of it such as “connected”, “connects”, and “connecting” as used in this description are intended to include indirect and direct connections unless otherwise indicated. For example, if a first device is connected to a second device, that coupling may be through a direct connection or through an indirect connection via other devices and connections. Similarly, if the first device is communicatively connected to the second device, communication may be through a direct connection or through an indirect connection via other devices and connections.

Use of language such as “at least one of X, Y, and Z”, “at least one of X, Y, or Z”, “at least one or more of X, Y, and Z”, “at least one or more of X, Y, and/or Z”, or “at least one of X, Y, and/or Z”, is intended to be inclusive of both a single item (e.g., just X, or just Y, or just Z) and multiple items (e.g., {X and Y}, {X and Z}, {Y and Z}, or {X, Y, and Z}). The phrase “at least one of” and similar phrases are not intended to convey a requirement that each possible item must be present, although each possible item may be present.

It is contemplated that any part of any aspect or embodiment discussed in this specification can be implemented or combined with any part of any other aspect or embodiment discussed in this specification, so long as such those parts are not mutually exclusive with each other.

The scope of the claims should not be limited by the embodiments set forth in the above examples, but should be given the broadest interpretation consistent with the description as a whole.

It should be recognized that features and aspects of the various examples provided above can be combined into further examples that also fall within the scope of the present disclosure. In addition, the figures are not to scale and may have size and shape exaggerated for illustrative purposes.

What is claimed is:

1. A Class A amplifier circuit comprising:
a first amplification stage including an operational amplifier having an output pin and a first compensation pin, the output pin being configured to output an amplified signal through a Class A/B output stage, and the first compensation pin, originally intended for internal frequency response adjustment, being repurposed to provide an internal signal prior to the Class A/B output stage; and
a second amplification stage arranged subsequent to the first amplification stage and including a discrete transistor,
wherein the first compensation pin of the operational amplifier is connected to the discrete transistor in the second amplification stage, such that the internal signal provided by the first compensation pin is amplified by the operational amplifier in Class A operation and is further amplified by the discrete transistor in Class A operation to generate an output signal of the Class A amplifier circuit.

2. The Class A amplifier circuit of claim 1, wherein the output pin of the operational amplifier is unutilized in the Class A amplifier circuit.

3. The Class A amplifier circuit of claim 1, wherein the first amplification stage further comprises:
a first DC servo sub-circuit configured to reduce DC offsets in the internal signal, the first DC servo sub-circuit including a second operational amplifier having:
a first input terminal connected to an output node of the discrete transistor in the second amplification stage;
a second input terminal connected to a ground node or a reference potential; and
a first output terminal connected to a second compensation pin of the operational amplifier in the first amplification stage, the second compensation pin being originally intended for offset voltage compensation,
wherein the first DC servo sub-circuit is configured to provide a corrective voltage to the second compensation pin, thereby reducing the DC offsets in the internal signal.

4. The Class A amplifier circuit of claim 3, wherein the first amplification stage further comprises:
a second DC servo sub-circuit configured to reduce DC offsets in an input signal to the operational amplifier, the second DC servo sub-circuit including a third operational amplifier having:
a third input terminal connected to one of input pins of the operational amplifier in the first amplification stage;
a fourth input terminal connected to a further ground node or a further reference potential; and
an second output terminal connected to the one of input pins of the operational amplifier in the first amplification stage,
wherein the second DC servo sub-circuit is configured to provide a corrective voltage to an input pin of the operational amplifier, thereby reducing the DC offsets in the input signal.

5. The Class A amplifier circuit of claim 3, wherein the operational amplifier further comprises a third compensation pin originally intended for offset trimming, the third compensation pin being connected to a further ground node through a resistor, the resistor being configured to stabilize voltage variations on the third compensation pin caused by feedback signals from the first DC servo sub-circuit.

6. The Class A amplifier circuit of claim 1, wherein the operational amplifier is configured as an inverting amplifier, an input signal of the operational amplifier being connected to an inverting input of the operational amplifier through an input resistor, and a feedback resistor being connected between the inverting input and an output node of the discrete transistor in the second amplification stage.

7. The Class A amplifier circuit of claim 1, wherein the operational amplifier is configured to accept balanced input signals, a positive input signal of the operational amplifier being connected to a non-inverting input of the operational amplifier through a positive input resistor, and a negative input signal of the operational amplifier being connected to an inverting input of the operational amplifier through a negative input resistor.

8. The Class A amplifier circuit of claim 1, wherein the discrete transistor in the second amplification stage is a NPN bipolar junction transistor (BJT) configured as an emitter follower, an emitter of the NPN BJT being connected to an output of the second amplification stage, a base of the NPN BJT being connected to the first compensation pin of the operational amplifier in the first amplification stage, and a collector of the NPN BJT being connected to a positive supply voltage.

9. The Class A amplifier circuit of claim 1, wherein the discrete transistor in the second amplification stage is a PNP BJT configured as an emitter follower, an emitter of the PNP BJT being connected to an output of the second amplification stage, a base of the PNP BJT being connected to the first compensation pin of the operational amplifier in the first amplification stage, and a collector of the PNP BJT being connected to a negative supply voltage.

10. The Class A amplifier circuit of claim 1, wherein the discrete transistor in the second amplification stage is a Metal-Oxide-Semiconductor Field Effect Transistor (MOSFET) configured as a source follower, a drain of the MOSFET being connected to an output of the second amplification stage, a gate of the MOSFET being connected to the first compensation pin of the operational amplifier in the first amplification stage, and a source of the MOSFET being connected to a negative supply voltage.

11. The Class A ower amplifier circuit of claim 1, wherein the discrete transistor in the second amplification stage is a junction field-effect transistor (JFET) configured as a source follower, a gate of the JFET being connected to the first compensation pin of the operational amplifier, a source of the JFET being connected to an output of the second amplification stage, and a drain of the JFET being connected to a positive supply voltage.

12. The Class A amplifier circuit of claim 1, wherein the second amplification stage comprises a current stabilization sub-circuit for maintaining a consistent operating point of the discrete transistor.

13. The Class A amplifier circuit of claim 12, wherein the current stabilization sub-circuit is configured as one of: a constant current source, a constant current sink, a Wilson current mirror, or a Widlar current source.

14. A method of operating a Class A amplifier circuit, the method comprising:
feeding an input signal to an operational amplifier of a first amplification stage, the operational amplifier having an output pin and a first compensation pin, the output pin being configured to output an amplified signal through a Class A/B output stage, and the first compensation pin, originally intended for internal frequency response adjustment, being repurposed to provide an internal signal prior to the Class A/B output stage;
amplifying the input signal by the operational amplifier in Class A operation to generate the internal signal;
outputting the internal signal from the first compensation pin of the operational amplifier to a discrete transistor of a second amplification stage; and
amplifying the internal signal by the discrete transistor in Class A operation to generate an output signal of the Class A amplifier circuit.

15. The method of claim 14, further comprising:
applying a corrective voltage to the second compensation pin to reduce DC offsets in the internal signal using a first DC servo sub-circuit, the first DC servo sub-circuit including a second operational amplifier having:
a first input terminal connected to an output node of the discrete transistor in the second amplification stage;
a second input terminal connected to a ground node or a reference potential; and
a first output terminal connected to a second compensation pin of the operational amplifier in the first amplification stage, the second compensation pin being originally intended for offset voltage compensation.

16. The method of claim 15, further comprising:
applying a corrective voltage to an input pin of the operational amplifier to reduce DC offsets in the input signal to the operational amplifier using a second DC servo sub-circuit, the second DC servo sub-circuit including a third operational amplifier having:
a third input terminal connected to one of the input pins of the operational amplifier in the first amplification stage;
a fourth input terminal connected to a further ground node or a further reference potential; and
a second output terminal connected to the one of the input pins of the operational amplifier in the first amplification stage.

17. The method of claim 15, further comprising:
stabilizing voltage variations on a third compensation pin of the operational amplifier caused by feedback signals from the first DC servo sub-circuit using a resistor, the third compensation pin being connected to a further ground node through the resistor, the third compensation pin being originally intended for offset trimming.

18. The method of claim 14, wherein the discrete transistor in the second amplification stage is a NPN bipolar junction transistor (BJT) configured as an emitter follower, an emitter of the NPN BJT being connected to an output of the second amplification stage, a base of the NPN BJT being connected to the first compensation pin of the operational amplifier in the first amplification stage, and a collector of the NPN BJT being connected to a positive supply voltage; or
wherein the discrete transistor in the second amplification stage is a PNP BJT configured as an emitter follower, an emitter of the PNP BJT being connected to an output of the second amplification stage, a base of the PNP BJT being connected to the first compensation pin of the operational amplifier in the first amplification stage, and a collector of the PNP BJT being connected to a negative supply voltage.

19. The method of claim 14, wherein the discrete transistor in the second amplification stage is a Metal-Oxide-Semiconductor Field Effect Transistor (MOSFET) configured as a source follower, a drain of the MOSFET being connected to an output of the second amplification stage, a gate of the MOSFET being connected to the first compensation pin of the operational amplifier in the first amplification stage, and a source of the MOSFET being connected to a negative supply voltage; or
wherein the discrete transistor in the second amplification stage is a junction field-effect transistor (JFET) configured as a source follower, a gate of the JFET being connected to the first compensation pin of the operational amplifier, a source of the JFET being connected to an output of the second amplification stage, and a drain of the JFET being connected to a positive supply voltage.

20. The method of claim 14, further comprising:
maintaining a consistent operating point of the discrete transistor in the second amplification stage using a current stabilization sub-circuit.
